(19) United States
(12) Patent Application Publication
(10) Pub. No.: US 2008/0233747 A1
(43) Pub. Date: Sep. 25, 2008

(54) Semiconductor Device Manufactured Using an Improved Plasma Etch Process for a Fully Silicided Gate Flow Process

(75) Inventors: Jinhan Choi, Frisco, TX (US); Freidoon Mehrad, Plano, TX (US); Frank S. Johnson, Richardson, TX (US)

Correspondence Address: TEXAS INSTRUMENTS INCORPORATED, P O BOX 655474, M/S 3999, DALLAS, TX, 75265, US

(73) Assignee: Texas Instruments Incorporated, Dallas, TX (US)

(21) Appl. No.: 11/690,198

(22) Filed: Mar. 23, 2007

(51) Int. Cl. H01L 21/302; H01L 21/461

(52) U.S. Cl. 438/689

(57) ABSTRACT

In one aspect, there us provided a method of manufacturing a semiconductor device that comprises placing an oxide layer over a gate electrode and sidewall spacers located adjacent thereto, placing a protective layer over the oxide layer, conducting a plasma etch to remove portions of the protective layer and the first oxide layer that are located over the gate electrode and expose a surface of the gate electrode, wherein the plasma etch is selective to polysilicon. A soft etch is conducted subsequent to the plasma etch. The soft etch includes an inorganic-based fluorine containing gas and an inert gas, wherein the plasma etch leaves a film on the gate electrode that inhibits silicidation of the gate electrode and wherein the soft etch removes the film. The gate electrode is silicided with a metal subsequent to conducting the soft etch.

### TECHNICAL FIELD

A semiconductor device and manufacture of that device is presented in which embodiments are directed to a semiconductor device and a method of manufacture therefore that uses a combination of a plasma etch and a soft etch to improve silicidation of gate electrodes.

### BACKGROUND

Metal gate electrodes are currently being investigated to replace polysilicon gate electrodes in today's ever shrinking and changing transistor devices. One of the principle reasons the industry is investigating replacing the polysilicon gate electrodes with metal gate electrodes is to solve problems of poly-depletion effects and boron penetration for future CMOS devices. Traditionally, a polysilicon gate electrode with an overlying silicide was used for the gate electrodes in CMOS devices. However, as device feature sizes continue to shrink, poly depletion and gate sheet resistance become serious issues when using polysilicon gate electrodes.

Accordingly, metal gates have been proposed. However, in order to optimize the threshold voltage (Vₜ) in high-performance devices, the metal gates need tunable work functions. For instance, the metal gates need tunable work functions for NMOS and PMOS devices similar to present polysilicon gate technology, requiring the work functions of metal gates to range from 4.1˜4.4 eV for NMOS and 4.8˜5.1 eV for PMOS.

Recently, silicided metal gates have been investigated based on the extension of existing self-aligned silicide (SALICIDE) technology. In this approach, polysilicon is deposited over the gate dielectric. A metal is deposited over the polysilicon and reacted to completely consume the polysilicon resulting in a fully silicided metal gate, rather than a deposited metal gate. The silicided metal gate provides a metal gate with the least perturbation to the conventional process and avoids contamination issues. Furthermore, poly doping has been shown to affect the work function of the silicided metal gates.

Complications can arise, however, during the silicidation process. For example, in some conventional processes and for reasons not fully known, all of the gate electrodes are not fully silicide as desired. In such instances, a number of electrodes may not get silicide, which causes yield loss and reliability issues.

Accordingly, what is needed in the art is a silicidation process that avoids the deficiencies of the conventional processes discussed above.

### SUMMARY

In one embodiment, the method comprises placing an oxide layer over a gate electrode and sidewall spacers located adjacent thereto, and a nitride-containing layer is placed over the oxide layer. A plasma etch is conducted to remove portions of the nitride-containing layer and the oxide layer that are located over the gate electrode and expose a surface of the gate electrode. In this embodiment, the plasma etch includes using a gas flow comprising CH₂F₂, CF₄, O₂, and an inert gas. The flow rate of CH₂F₂ is about 90 sccm, the flow rate of CF₄ is about 30 sccm, the flow rate of O₂ is about 15 sccm, and the flow rate of the inert gas is about 50 sccm. The plasma etch is conducted at a pressure of about 5 millitorr, at a power of about 550 watts, and at a bias of about 300 volts. Subsequent to the plasma etch, a soft etch is conducted on the surface of the gate electrode. In this particular embodiment, the soft etch includes using SF₆, wherein a flow rate of SF₆ is about 5 sccm and is conducted at a power of 200 watts with a bias of about 0.0 volts and at a pressure of about 3 millitorr. The gate electrode is silicided with a metal subsequent to conducting the soft etch.

In another embodiment, a method of manufacturing a semiconductor device comprises placing a first oxide layer over a gate electrode and sidewall spacers located adjacent thereto, placing a nitride-containing layer over the oxide layer, placing a second oxide layer over the nitride-containing layer, and removing a portion of the second oxide layer to expose the nitride-containing layer. This embodiment further includes conducting a plasma etch to remove portions of the nitride-containing layer and the first oxide layer that are located over the gate electrode and expose a surface of the gate electrode. The plasma etch is selective to polysilicon and has an oxide/nitride selectivity ranging from about 0.4 to about 1.0, an oxide/polysilicon selectivity ranging from about 13.0 to about 40.0. A soft etch is conducted subsequent to the plasma etch and includes using an inorganic-based fluorine containing gas and an inert gas, wherein the soft etch has a nitride/oxide selectivity ranging from about 1.0 to about 1.2 and an oxide/polysilicon selectivity of about 0.7. The gate electrode is silicided with a metal subsequent to conducting the soft etch.

Another embodiment provides a method of manufacturing a semiconductor device, comprising placing an oxide layer over a gate electrode and sidewall spacers located adjacent thereto, placing a protective layer over the oxide layer, conducting a plasma etch to remove portions of the protective layer and the first oxide layer that are located over the gate electrode and expose a surface of the gate electrode, wherein the plasma etch is selective to polysilicon. A soft etch is conducted subsequent to the plasma etch. The soft etch includes an inorganic-based fluorine containing gas and an inert gas, wherein the plasma etch leaves a film on the gate electrode that inhibits silicidation of the gate electrode and wherein the soft etch removes the film. The gate electrode is silicided with a metal subsequent to conducting the soft etch.

Another embodiment provides a semiconductor device that comprises a plurality of silicided gate electrodes having source/drains that are located in wells associated therewith. The silicided gate electrodes are formed by: conducting a plasma etch to remove portions of the nitride-containing layer and the oxide layer located over the gate electrode and expose a surface of the gate electrode. The plasma etch includes using a gas flow comprising CH₂F₂, CF₄, O₂, and an inert gas. A flow rate of CH₂F₂ is about 90 sccm, a flow rate of CF₄ is about 30 sccm, a flow rate Of O₂ is about 15 sccm, and a flow rate of the inert gas is about 50 sccm. The plasma etch is conducted at a pressure of about 5 millitorr, at a power of about 550 watts and at a bias of about 300 volts; conducting. A soft etch is conducted on the surface of the gate electrode and includes using an inorganic-based fluorine containing gas and an inert gas subsequent to conducting the plasma etch. A flow rate of SF₆ is about 5 sccm and the soft etch is conducted at a power of about 200 watts with a bias of about 0.0 volts and at a pressure of about 3 millitorr. The gate electrode is silicided with a metal subsequent to conducting the soft etch. The semiconductor device further includes dielectric layers located over the silicided gate electrodes and interconnects formed over or within the dielectric layers that interconnect the silicided gate electrodes and the source/drains.

### BRIEF DESCRIPTION OF THE DRAWINGS

For a better understanding, reference is now made to the following descriptions taken in conjunction with the accompanying drawings, in which:

FIG. 1 illustrates a partial view of a semiconductor device manufactured by the invention;

FIGS. 2A-2B illustrate a conventional process of forming source/drains in a semiconductor substrate and adjacent gate electrodes;

FIGS. 3-5 illustrate embodiments where a first oxide layer, protective layer and a second oxide layer are subsequently deposited over the gate electrodes;

FIG. 6 illustrates an embodiment where a portion of the second oxide layer is removed to expose the protective layer;

FIGS. 7A-7D illustrate embodiments where a plasma etch is conducted to removed portions of the oxide and protective layers and where a soft etch is conducted to removed a film that results from the plasma etch; and

FIGS. 8-10 illustrate how conventional steps might be used to complete the semiconductor device and incorporate it into an integrated circuit.

### DETAILED DESCRIPTION

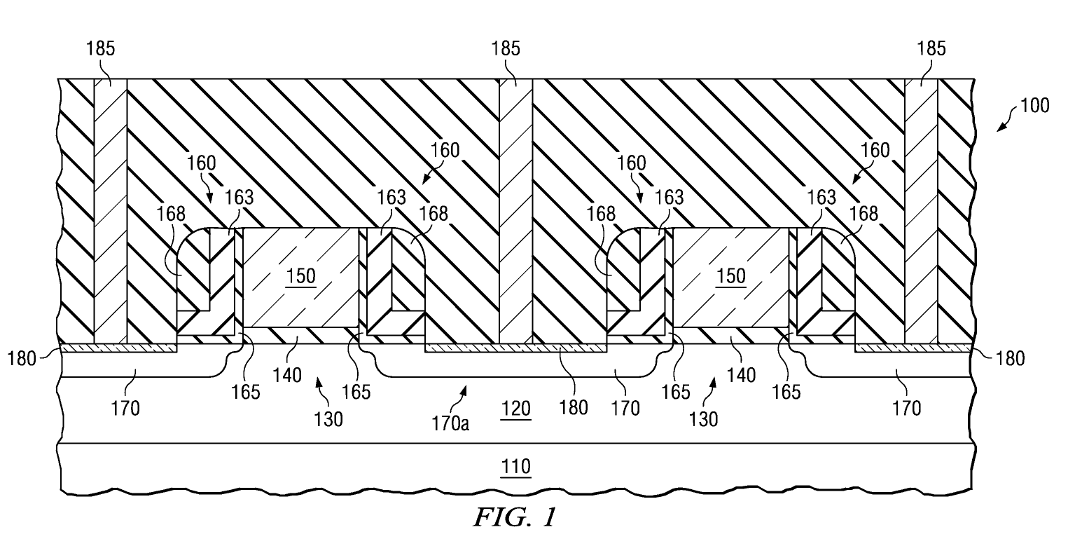

FIG. 1 illustrates a partial view of a semiconductor device 100, as provided by one embodiment of the invention. The semiconductor device 100 includes a substrate 110. Located within the substrate 110 in the embodiment of FIG. 1 is a well region 120. Located over the substrate 110 and well region 120 are silicide gate structures 130.

In the illustrated embodiment of FIG. 1, the gate structures 130 each include a gate oxide 140 located over the substrate 110, as well as a fully silicided gate electrode 150 located over the gate oxide 140. The silicided gate electrode 150 may have a variety of thicknesses. For example, the thickness may range from about 50 nm to about 150. The silicided gate electrode 150 may comprise a number of different materials. For instance, the silicided gate electrode 150 may comprise nickel, however, it is envisioned that the silicided gate electrode 150 could also comprise cobalt, platinum, titanium, tantalum, molybdenum, tungsten and combinations thereof.

The silicided gate electrodes 150 may also include a dopant or combination of several types of dopants therein. The dopant, such as boron, phosphorous, arsenic or another similar dopant based on whether the semiconductor device 100 is operating as a PMOS device or an NMOS device, is configured to tune the minimum energy required to bring an electron from the Fermi level to the vacuum level, or the so called work function.

The gate structure 130 may further include conventional gate sidewall spacers 160 flanking both sides of the silicided gate electrode 150 and gate oxide 140. The gate sidewall spacers 160 may each include one or more different layers. For instance the gate sidewall spacers 160 may also include nitride-containing spacers 163 and sidewall oxides 165 and 168. It should be noted that the gate sidewall spacers 160 may comprise many different types and numbers of layers.

The semiconductor device 100 may also include conventional source/drain regions 170 located within the substrate 110 and proximate the gate oxide 140 and within a moat region 170a located between the gate electrodes 150. Located within the source/drain regions 170 are silicided source/drain contact pads 180, on which contact structures 185 are located. The silicided source/drain contact pads 180 in one embodiment may comprise nickel silicided source/drain contact pads. Nonetheless, other silicidation materials could be used to form the silicided source/drain contact pads 180 and remain within the scope of the present invention. The silicided source/drain contact pads 180 may have a depth into the source/drain regions 170 ranging from about 10 nm to about 30 nm, among others.

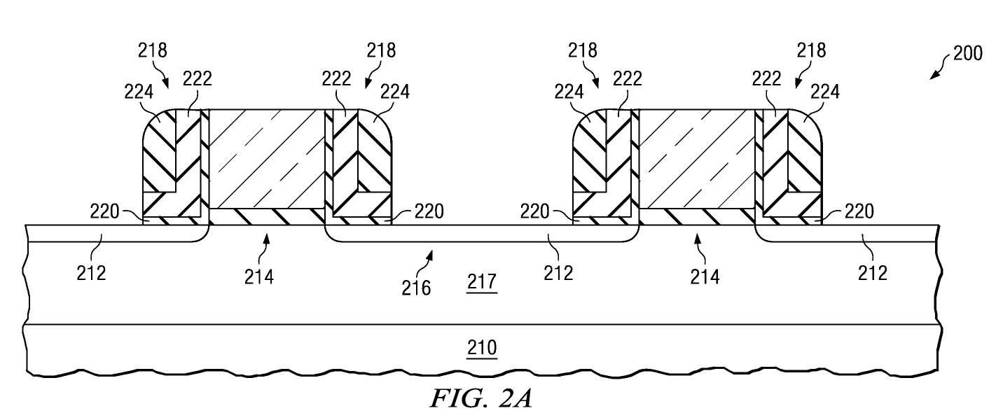

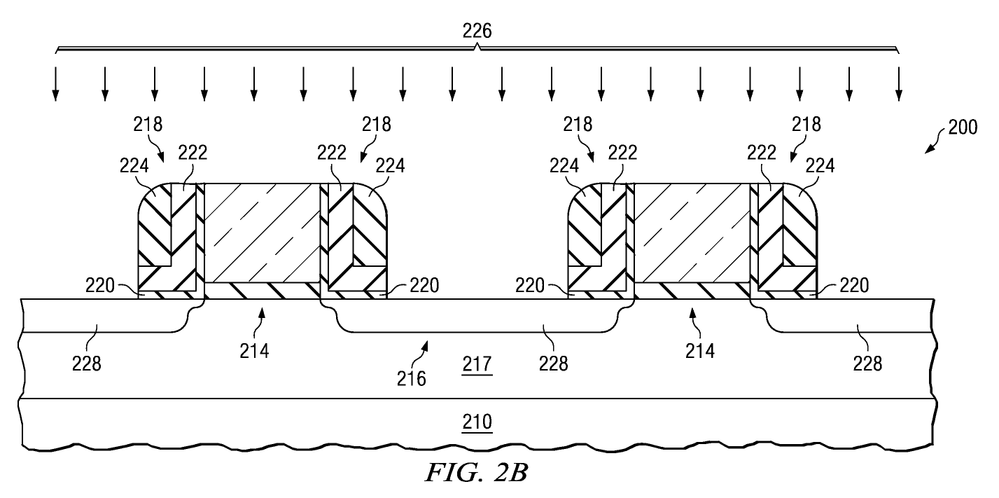

FIGS. 2A-2B, illustrate views of a semiconductor device 200 at different stages of manufacturer. Conventional processes and material may be used to form the semiconductor device shown in FIG. 2A. At this stage of manufacture, medium doped drain (MDD) regions 212 may be conventionally formed adjacent the gate structures 214 and in a moat region 216 of a well 217. Sidewall spacers 218 have also have been conventionally formed at this point. The sidewall spacers 218 may have different configurations. In the illustrated embodiment of FIG. 2A, the sidewall spacers 218 include an oxide layer 220 over which is located a nitride layer 222 and over which is located another oxide layer 224. The layers have been etched to form a conventional L-shaped sidewall spacer. The formation of the sidewall spacers 218 may be followed by a conventional source/drain implant 226 as shown in FIG. 2B, which forms deep source/drains 228 adjacent each of the gate structures 214 and within the moat region 216. Generally the source/drain implant 226 involves a high dopant concentration that has a peak dopant concentration ranging from about 1E18 atoms/cm³ to about 1E21 atoms/cm³. Also, the highly doped source/drain implant 226 should typically have a dopant type opposite to that of the well region 217 in which it is implanted. Following the source/drain implant 226, a conventional source/drain anneal may be conducted to activate and form the source/drain regions 228. In one embodiment, the source/drain anneal may be conducted at a temperature ranging from about 1000° C. to about 1100° C. and a time period ranging from about 1 second to about 5 seconds. It should be noted that other temperatures, times, and processes could be used to activate the source/drain regions 228 and such processes are known to those skilled in the art.

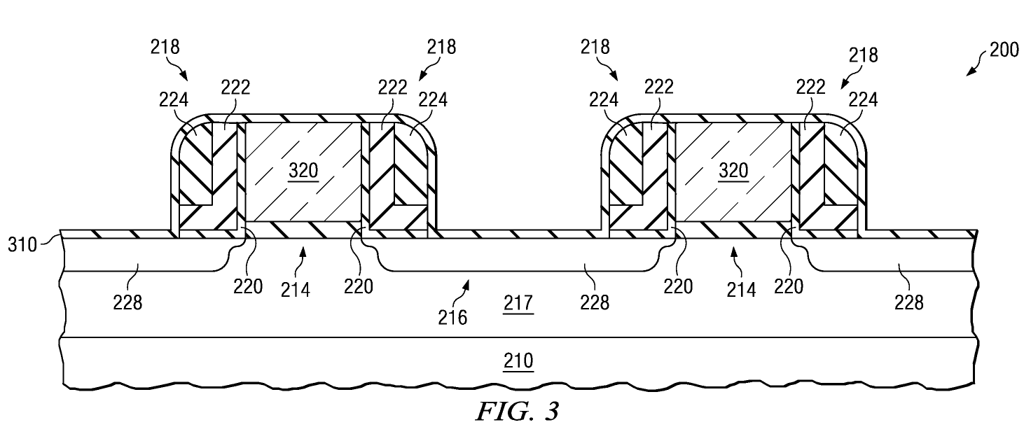

FIG. 3 illustrates a view of the semiconductor device 200 of FIG. 2B following the deposition of a capping layer 310. The capping layer 310 may be formed using conventional processes and materials. For example, the capping layer 310 may be silicon dioxide. Conventional deposition processes, such as chemical vapor deposition or chemical vapor deposition may be used to deposit the capping layer 310. The thickness of the cap layer 310 may range from about 5 nm to about 15 nm. In the embodiment shown in FIG. 3, the capping layer 310 is conformally deposited over both gate structures 214, the source/drains 228 and the moat region 216. As discussed below, the capping layer 310 helps to protect the moat region 216 and source/drains 228 during the silicidation of the gate electrode 320, and it also serves to protect the gate electrodes 320 from subsequent etch processes that might otherwise remove excessive amounts of the gate electrodes 320.

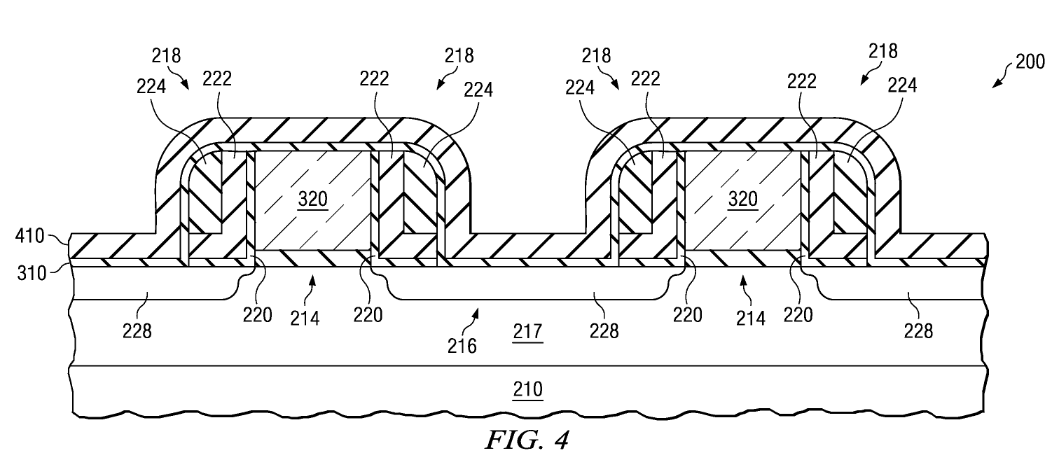

FIG. 4 illustrates the semiconductor device 200 of FIG. 3 following the deposition of a protective layer 410 over the capping layer 310. The protective layer 410 may be a single layer that is capable of protecting the source/drains 228 and moat region 216 during a silicidation process, or it may be used in conjunction with other underlying layers, such as the capping layer 310 to protect those regions during a silicidation process. The protective layer 410, in one embodiment, may comprise or contain nitride, oxide or a combination thereof. For example, the protective layer 410 may be silicon nitride or silicon oxynitride. However, other materials, such as silicon carbide, that are capable of protecting the moat region 216 and source/drains 228 from the subsequent gate silicidation process may also be used. Conventional deposition processes, such as chemical vapor deposition, physical vapor deposition or atomic layer deposition may be used to deposit the protective layer 410. The thickness of the protective layer 410 may range from about 20 nm to about 40 nm. As shown in the embodiment illustrated in FIG. 4, the protective layer 410 is conformally deposited over both gate electrodes 320, the source/drains 228 and the moat region 216. Moreover, as discussed below, the protective layer 410 helps to protect the moat region 216 and source/drains 228 during the silicidation of the gate electrodes 320.

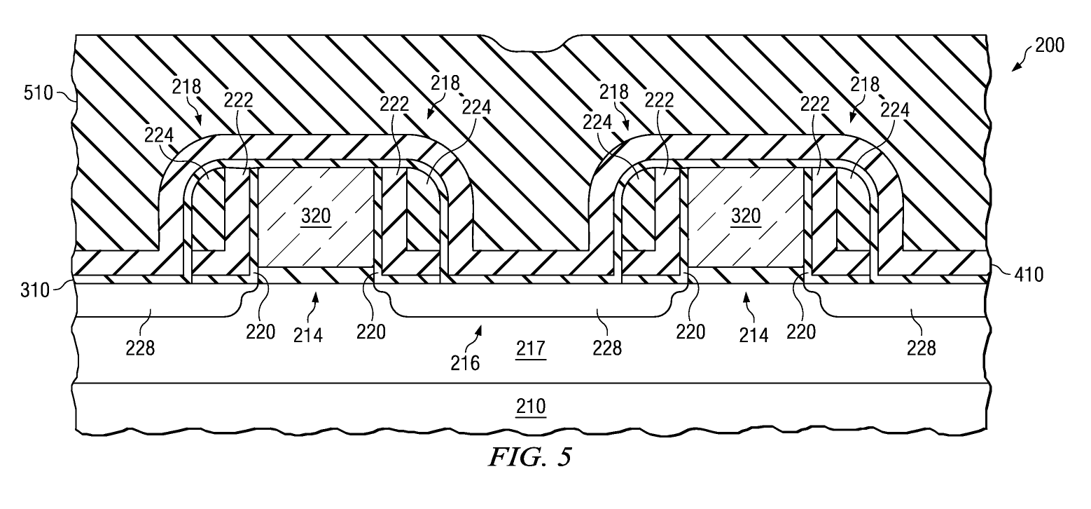

FIG. 5 illustrates the semiconductor device 200 of FIG. 4 following the deposition of a dielectric layer 510 over the protective layer 410. In one embodiment, the dielectric layer 510 may be silicon dioxide or a combination of tetra orthosilciate (TEOS) and ozone. Conventional deposition processes, such as chemical vapor deposition, physical vapor deposition, or high aspect ration processes (HARP), may be used to deposit the dielectric layer 510. In one embodiment, the dielectric layer 510 is TEOS and ozone, and the thickness of the dielectric layer 510 may vary with a preferred thickness being about 200 nm. As shown in the embodiment of FIG. 5, the dielectric layer 510 is also conformally deposited over the protective layer 410, including both gate electrodes 320, the source/drains 228, and the moat region 216. As discussed below, the dielectric layer 510 inhibits the removal of the protective layer 410 located over the source/drains 228 and the moat region 216 during an etch process that is conducted to remove a portion of the protective layer 410 located over each of the gate electrodes 320.

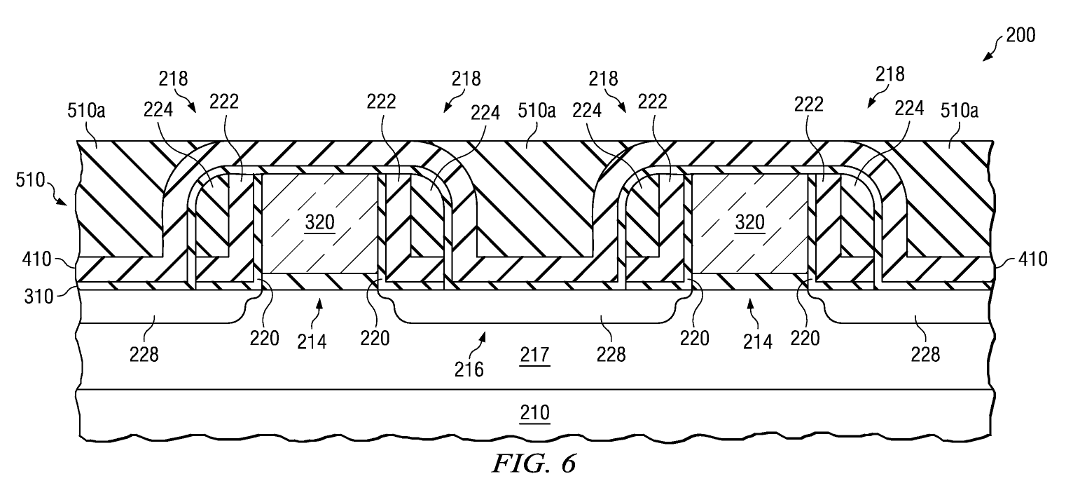

FIG. 6 illustrates the semiconductor device 200 of FIG. 5 following a partial removal of the dielectric layer 510. The dielectric layer 510 is removed to expose the underlying protective layer 410 that is substantially located over the gate electrodes 320. This partial removal exposes a portion of the protective layer 410 so that it can be removed by a subsequent process. Portions 510a of the dielectric layer 510 may remain over the moat region 216 and the source/drain regions 228. The presence of the remaining portions 510a prevents or limits unwanted removal of the protective layer 410 overlying these regions during subsequent processing steps. The dielectric layer 510 may be removed using any conventional process. For example, a chemical/mechanical process (CMP) may be used to remove the dielectric layer 510 down to and substantially stopping on the protective layer 410. In some embodiments, a small portion (less than 2 nm) of the protective layer 410 may be removed during this process. However, uniform removal of the protective layer 410 may not occur across the substrate 210, and in such instances there may be areas where the protective layer 410 may be substantially removed.

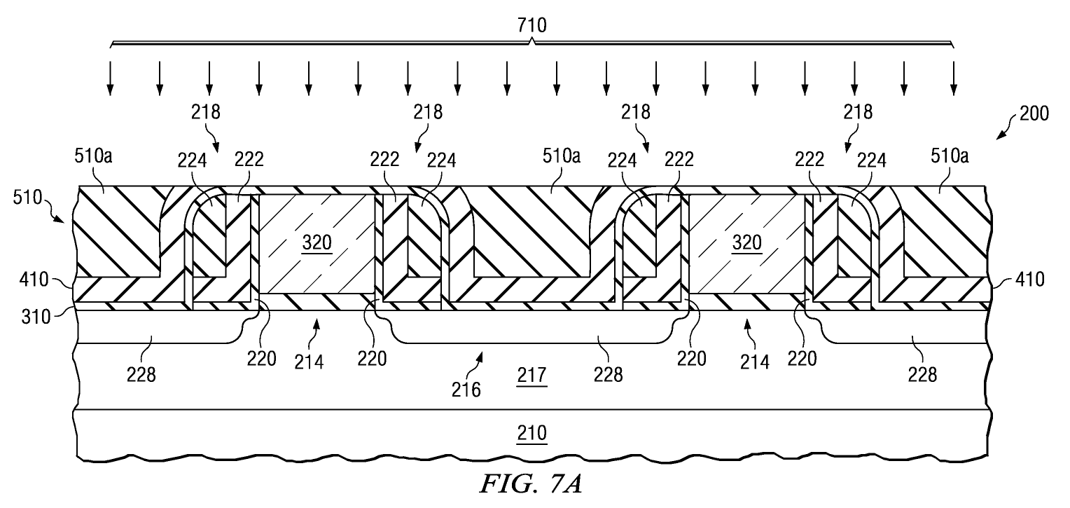

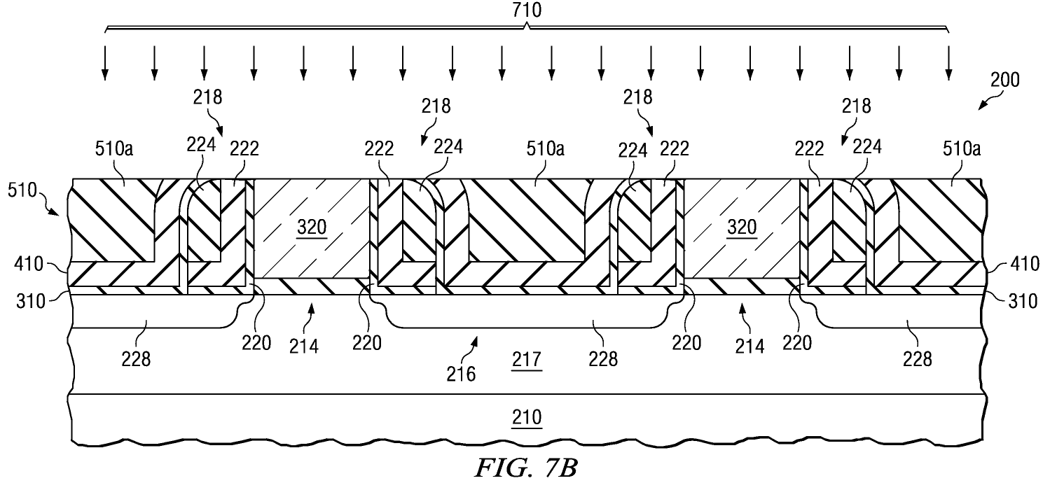

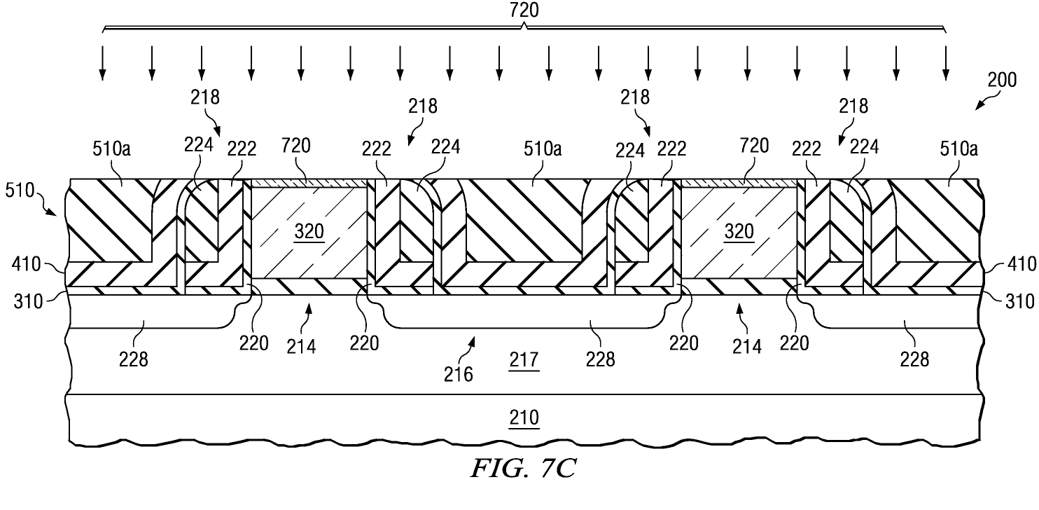

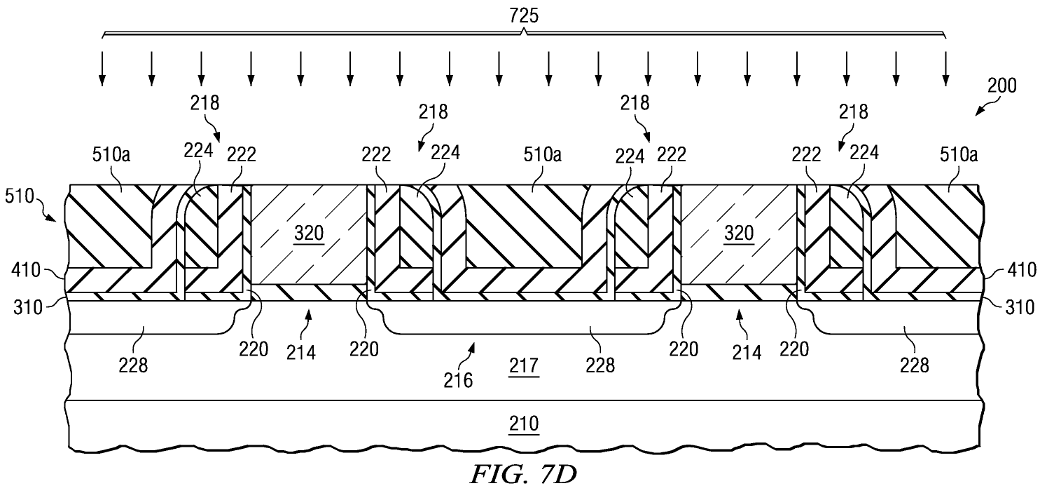

FIG. 7 illustrates a view of the semiconductor device 200 of FIG. 6 during an etch process 710, such as a plasma etch. With the invention, it has been presently found that conventional etch processes can result in (i.e., “leave”) some type of damage to the gate electrodes 320 or a film being left or formed over the gate electrodes 320. For purposes of discussion, it should be understood that whether the result of the etch 710 causes damage to the surface of the gate electrodes 320 or leaves some type of film is not fully understood. Thus, for general purposes, this damage or film will be referred to herein as a film for ease of discussion. What is recognized is that this film interferes with proper silicidation of the gate electrodes, and thus, should be removed. The presence of this film was previously unrecognized and was labor intensive to discover in that the film occurred in a small number of transistors on any given chip. Thus, numerous wafers were examined over an extended period of time before the film was identified. Upon discovery of the film, it was realized that the film inhibits proper silicidation of the gate electrodes 320. The various embodiments of the invention address this issue by providing an etch process that removes the film without damaging or over-etching the gate electrodes 320.

In one embodiment, the etch 710 is conducted to remove the protective layer 410 and the underlying oxide layer 310 that are located over the gate electrodes 320, yet is selective to the material that comprises the gate electrodes 320. The etch 710 is configured to uniformly remove the protective layer 410 and the oxide layer 310 and have a controlled landing on the gate electrode 320. In one aspect, the gate electrodes 320 may be polysilicon. In such instances, the etch 710 would be selective to polysilicon; that is, the etch 710 etches the polysilicon at a significantly slower rate (as much as about 13 times slower) than the protective layer 410 or the oxide layer 310. This selectivity is beneficial in providing a controlled landing on the gate electrodes 320 so that the gate electrodes 320 are not significantly damaged or over-etched. This selectivity is also beneficial to prevent over-etch of the gate electrodes 320 in those areas where the CMP might have removed more of the protective layer 410 and the oxide layer 310. Moreover, etch 710 is configured to uniformly etch the oxide and nitride.

For example, in those embodiments where the gate electrodes 320 comprise polysilicon, the etch 710 may have an oxide/polysilicon selectivity ranging from about 13 to about 40.0. In another embodiment, the protective layer 410 contains nitrogen, and in this particular embodiment, the oxide/nitride selectivity may range from about 0.4 to about 1.0, and the oxide/polysilicon selectivity may also range from about 13 to about 40 as with the previous embodiment. As seen, the etch rate of the oxide/nitride is similar, but is much higher than the etch rate of the polysilicon. This facilitates a uniform removal of the protective layer 410 and the oxide layer 310 and provides a controlled landing on the gate electrodes 320.

In another aspect where the protective layer 410 includes nitrogen, the oxide/nitride selectivity may be about 0.9, the nitride/polysilicon selectivity may be about 14.4 and the oxide/polysilicon selectivity may be about 13.1.

An example of the type of chemistry that can be used in etch 710 is a gas flow comprising CH₂F₂, CF₄, O₂, and an inert gas, such as He or Ar. In one embodiment, the flow rate of CH₂F₂ may be about 90 sccm, the flow rate of CF₄ may ranging from about 30 sccm to about 45 sccm, the flow rate of O₂ may range from about 10 to about 15 sccm, and the flow rate of the inert gas may be about 50 sccm. Further, the etch 710 may be conducted at a pressure of about 5 to 8 millitorr, at a power of about 500 watts, and at a voltage bias of about 300 volts. In one case, a flow rate of CF₄ of about 30 sccm and a flow rate of O₂ of about 15 yielded good results. Additionally, the polysilicon etch rate may range from about 6.7 nm/min to about 9.8 nm/min and the oxide etch rate may range from about 95.3 nm/min to about 87.9 nm/min, with 6.7 nm/min and 87.9 min, in one embodiment, obtaining good results.

The etch is conducted until the protective layer 410 and the oxide layer 310 are removed from over the top portion of the gate electrodes 320 as shown in FIG. 7B. As mentioned above, it has been unexpectedly found that the etch 710 results in or leaves a film 720, as seen in FIG. 7C. It also has been found that this film 720 inhibits subsequent silicidation processes.

In view of the discovery of the existence of film 720, a soft etch 725 is conducted to remove the film 720. As used herein, a soft etch is an etch that uses an inorganic-based fluorine chemistry (i.e., one that does not contain carbon) and uses a low bias potential energy level (e.g., one that is very close to zero volts) during the etch. Due to the very low potential energy levels, the soft etch effectively does not contain an ion etching. As such, the film 720 can be removed without over etching the gate electrodes 320. An inert gas, such as helium or argon, may also be used in the soft etch 725. In one embodiment, the soft etch 725 has a nitride/oxide selectivity ranging from about 1.0 to about 1.2 and an oxide/polysilicon selectivity of about 0.7.

In another embodiment, the inorganic fluorine gas may be F₂ or NF₃, and in yet another embodiment that yields good results, the inorganic-based fluorine gas is SF₆. In one aspect of this embodiment, the flow rate of SF₆ is about 5 sccm and the soft etch is conducted at a power of about 200 watts with a bias of about 0.0 volts and at a pressure of about 3 millitorr The soft etch is conducted for until the film 720 is removed, as shown in FIG. 7D. The amount of time that soft etch 725 is conducted will depend on the thickness of the film 720. For example, in one embodiment, the etch rate of the soft etch 725 on polysilicon may be 11 nm/min, and in those instances where the thickness of the film 720 is about 6 nm, the etch may be conducted for less than 30 seconds.

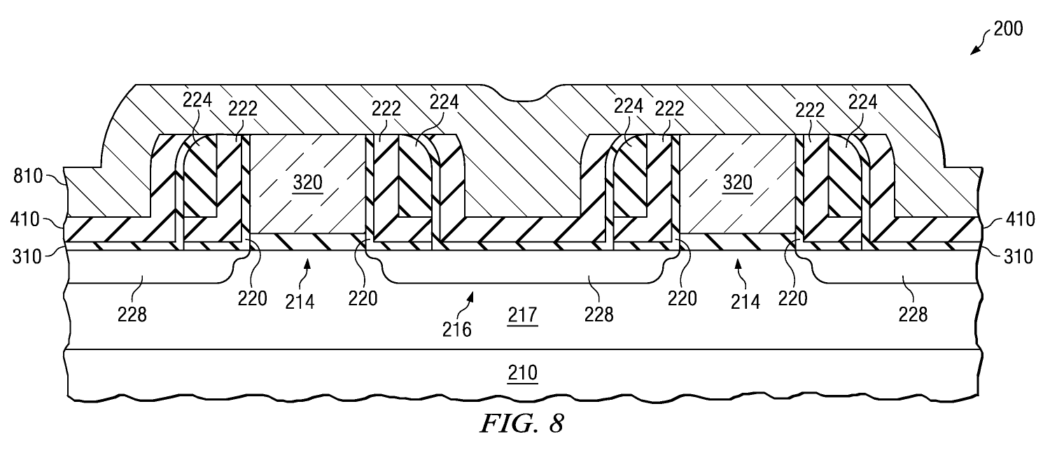

Following the removal of the film 720, a metal layer 810 is deposited over the gate electrodes 320, as shown in FIG. 8. Conventional deposition processes may be used to place the metal layer 810 over the exposed surfaces of the gate electrodes 320, source/drains 228 and the moat region 216. The thickness of the metal layer 810 may vary and will depend, in some embodiments, on the thickness of the gate electrodes 320. For example, in one embodiment where the thicknesses of the gate electrodes 320 are about 80 nm thick, the thickness of the metal layer 810 will be about 60 nm. Preferably, the metal layer 810 is thick enough such that full silicidation of the gate electrodes 320 occurs. However, in other embodiments, full silicidation may not be necessary. In such cases, the metal layer 810 may be thinner. The silicidation can be conducted until the desired work function of the respective gate electrodes 320 is achieved or the gate electrodes 320 are fully silicided.

The metal layer 810 may be nickel or cobalt or a combination thereof. In those embodiments where the metal layer 810 is nickel, an exemplary silicide process comprises placing a blanket of nickel layer over the gate electrodes 320. As it takes approximately 1 nm of nickel to fully silicidize approximately 1.8 nm of polysilicon, the thickness of the blanket layer of nickel should be at least 56% of the thickness of the gate electrode 320. To be comfortable, however, it is suggested that the thickness of the layer of nickel should be at least 60% of the thickness of the gate electrode 320. Thus, where the thickness of the gate electrode 320 ranges from about 50 nm to about 150 nm, as described above, the thickness of the blanket layer of nickel should range from approximately 30 nm to about 90 nm. It should also be noted that the blanket layer of metal layer 810 may comprise a number of different metals or combinations of metals, such as nickel and cobalt, while staying within the scope of the present invention. The nickel layer and the gate electrodes 320 are subjected to a thermal anneal having a temperature ranging from about 400 degrees centigrade to about 600 degrees centigrade and for a period of time ranging from about 10 seconds to about 100 seconds. It should be noted, however, that the silicidation process may vary depending on the amount of silicidation that is desired and the materials that are used to silicide the gate electrodes 320. For example, if the gate electrodes 320 are silicided with a combination of cobalt and nickel, then the silicidation process parameters and percentages of materials used will be different than those just stated above. Those who are skilled in the art will understand how to achieve the desired degree of silicidation when using such metal combinations.

After siliciding the gate electrode 320, any remaining or unreacted metal materials can be removed using conventional processes. It should be noted that the silicide does not form on the moat region 216 or the source/drains 228 at this time because the protective layer 410 and the oxide layer 310 block the silicidation process from affecting those regions.

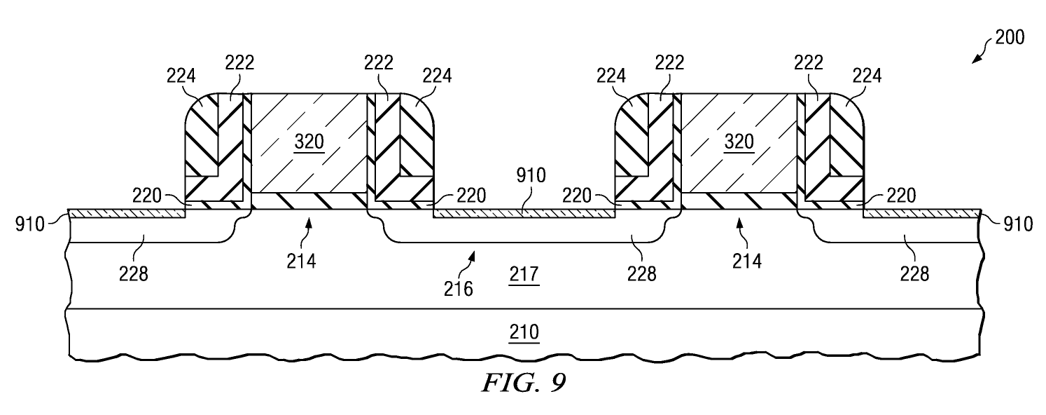

Following the silicidation process and removal of the excess metal layer 810, the remaining portions of the protective layer 410 and the oxide layer 310. A conventional source/drain silicidation process may then be conducted to form silicidation contacts 910 and arrive at the semiconductor device 200 shown in FIG. 9.

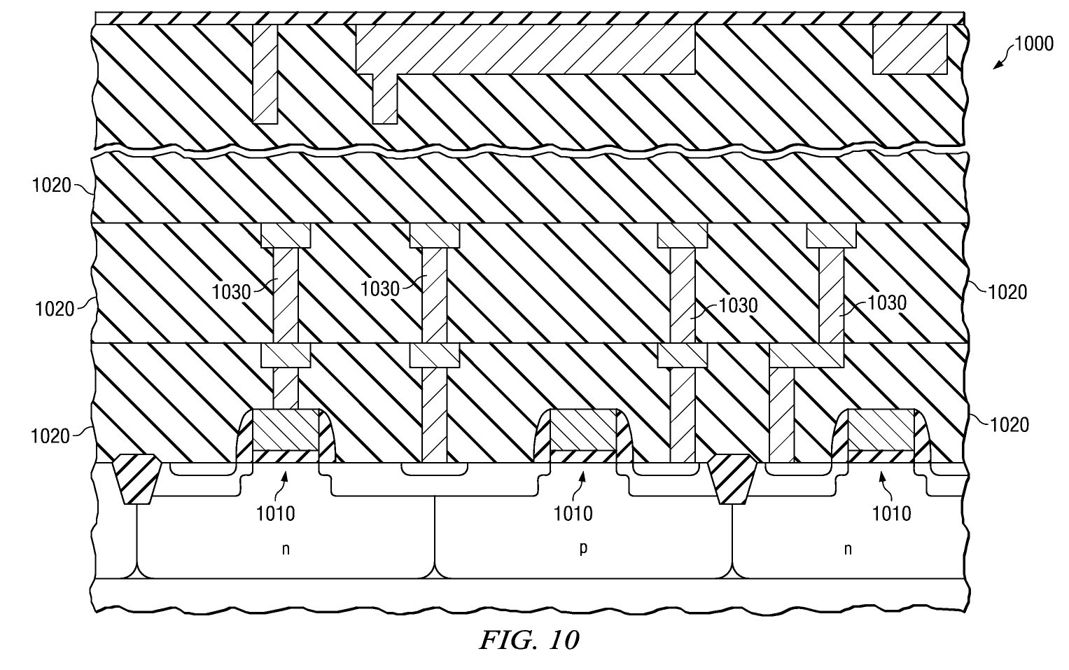

FIG. 10 illustrates semiconductor device 200 configured as an integrated circuit (IC) 1000. The structure shown in FIG. 9, generally designated as device 1010, including the various embodiments discussed herein, may be incorporated into the IC 1000 by conventional process. The devices 1010 may include a wide variety of devices, such as transistors used to form CMOS devices, BiCMOS devices, Bipolar devices, as well as capacitors or other types of devices. The IC 1000 may further include passive devices, such as inductors or resistors, or it may also include optical devices or optoelectronic devices. Those skilled in the art are familiar with these various types of devices and their manufacture. In the particular embodiment illustrated in FIG. 10, the devices 1010 are transistors over which dielectric layers 1020 are located, and the transistors may be fabricated in accordance with the various embodiments discussed above. Additionally, interconnect structures 1030, which may include damascene, dual damascene or other convention interconnect structures are located within the dielectric layers 1020 to interconnect various devices 1010, thus, forming an operational integrated circuit 1000.

Those skilled in the art will appreciate that other and further additions, deletions, substitutions and modifications may be made to the described embodiments without departing from the scope of the invention.

What is claimed is:

1. A method of manufacturing a semiconductor device, comprising:
placing an oxide layer over a gate electrode and sidewall spacers located adjacent thereto;
placing a nitride-containing layer over the oxide layer;
conducting a plasma etch to remove portions of the nitride-containing layer and the oxide layer located over the gate electrode and expose a surface of the gate electrode, wherein the plasma etch includes a gas flow comprising CH₂F₂, CF₄, O₂, and an inert gas, and wherein a flow rate of CH₂F₂ is about 90 sccm, a flow rate of CF₄ is about 30 sccm, a flow rate of O₂ is about 15 sccm, and a flow rate of the inert gas is about 50 sccm, and wherein the plasma etch is conducted at a pressure of about 5 millitorr, at a power of about 550 watts, and at a bias of about 300 volts;
conducting a soft etch on the surface of the gate electrode, including using SF₆, wherein a flow rate of SF₆ is about 5 sccm and is conducted at a power of 200 watts with a bias of about 0.0 volts and at a pressure of about 3 millitorr; and
siliciding the gate electrode with a metal subsequent to conducting the soft etch.

2. The method recited in claim 1, wherein the oxide layer is a first oxide layer and the method further includes depositing a second oxide layer over the nitride-containing layer and removing at least a portion of the second oxide layer with a chemical/mechanical process to expose the nitride-containing layer.

3. The method recited in claim 1, wherein the plasma etch leaves a film on the gate electrode that inhibits silicidation of the gate electrode and wherein the soft etch removes the film.

4. The method recited in claim 1, wherein the semiconductor device is an integrated circuit and the method further includes forming a plurality of gate electrodes, and source/drains in wells adjacent the gate electrodes, forming dielectric layers over the gate electrodes, and forming interconnects over or within the dielectric layers to interconnect the gate electrodes and source/drains.

5. A method of manufacturing a semiconductor device, comprising:
placing a first oxide layer over a gate electrode and sidewall spacers located adjacent thereto;
placing an nitride-containing layer over the oxide layer;
placing a second oxide layer over the protective layer;
removing a portion of the second oxide layer to expose the nitride-containing layer;
conducting a plasma etch to remove portions of the nitride-containing layer and the first oxide layer located over the gate electrode and expose a surface of the gate electrode, wherein the plasma etch is selective to polysilicon and has an oxide/nitride selectivity ranging from about 0.4 to about 1.0, an oxide/polysilicon selectivity ranging from about 13 to about 40.0;
conducting a soft etch subsequent to the plasma etch, the soft etch including an inorganic-based fluorine containing gas and an inert gas, wherein the soft etch has a nitride/oxide selectivity ranging from about 1.0 to about 1.2 and an oxide/polysilicon selectivity of about 0.7; and
siliciding the gate electrode with a metal subsequent to conducting the soft etch.

6. The method recited in claim 5, wherein the plasma etch includes a gas flow comprising CH₂F₂, CF₄, O₂, and an inert gas and wherein a flow rate of CH₂F₂ is about 90 sccm, a flow rate of CF₄ is about 30 sccm, a flow rate of O₂ is about 15 sccm, and a flow rate of the inert gas is about 50 sccm.

7. The method recited in claim 6, wherein the plasma etch is conducted at a pressure of about 5 millitorr, at a power of about 550 watts and at a bias of about 300 volts.

8. The method recited in claim 5, wherein the inorganic-based fluorine gas is F₂ or NF₃.

9. The method recited in claim 5, wherein the inorganic-based fluorine gas is SF₆ and a flow rate of SF₆ is about 5 sccm and the soft etch is conducted at a power of about 200 watts with a bias of about 0.0 volts and at a pressure of about 3 millitorr.

10. The method recited in claim 5, wherein the plasma etch leaves a film on the gate electrode that inhibits silicidation of the gate electrode and wherein the soft etch removes the film.

11. The method recited in claim 5, wherein the semiconductor device is an integrated circuit and the method further includes forming a plurality of gate electrodes, and source/drains in wells adjacent the gate electrodes, forming dielectric layers over the gate electrodes, and forming interconnects over or within the dielectric layers to interconnect the gate electrodes and source/drains.

12. A method of manufacturing a semiconductor device, comprising:
placing an oxide layer over a gate electrode and sidewall spacers located adjacent thereto;
placing a protective layer over the oxide layer;
conducting a plasma etch to remove portions of the protective layer and the first oxide layer located over the gate electrode and expose a surface of the gate electrode, wherein the plasma etch is selective to polysilicon;
conducting a soft etch subsequent to the plasma etch, the soft etch including an inorganic-based fluorine containing gas and an inert gas, wherein the plasma etch leaves a film on the gate electrode that inhibits silicidation of the gate electrode and wherein the soft etch removes the film; and
siliciding the gate electrode with a metal subsequent to conducting the soft etch.

13. The method recited in claim 12, wherein the plasma etch includes a gas flow comprising CH₂F₂, CF₄, O₂, and an inert gas and wherein a flow rate of CH₂F₂ is about 90 sccm, a flow rate of CF₄ is about 30 sccm, a flow rate of O₂ is about 15 sccm, and a flow rate of the inert gas is about 50 sccm.

14. The method recited in claim 13, wherein the plasma etch is conducted at a pressure of about 5 millitorr, at a power of about 550 watts and at a bias of about 300 volts.

15. The method recited in claim 12, wherein the plasma etch has an oxide to polysilicon selectivity ranging from about 13 to about 40.0.

16. The method recited in claim 12, wherein the soft etch has a nitride/oxide selectivity ranging from about 1.0 to about 1.2 and an oxide/polysilicon selectivity of about 0.7.

17. The method recited in claim 12, wherein the inorganic-based fluorine gas is F₂ or NF₃.

18. The method recited in claim 12, wherein the inorganic-based fluorine gas is SF₆ and a flow rate of SF₆ is about 5 sccm and the soft etch is conducted at a power of about 200 watts with a bias of about 0.0 volts and at a pressure of about 3 millitorr.

19. The method recited in claim 12, wherein the semiconductor device is an integrated circuit and the method further includes forming a plurality of gate electrodes, and source/drains in wells adjacent the gate electrodes, forming dielectric layers over the gate electrodes, and forming interconnects over or within the dielectric layers to interconnect the gate electrodes and source/drains.

20. A semiconductor device comprising:
a plurality of silicided gate electrodes having source/drains that are located in wells associated therewith, the silicided gate electrodes having been formed by:
conducting a plasma etch to remove portions of the nitride-containing layer and the oxide layer located over the gate electrode and expose a surface of the gate electrode, wherein the plasma etch includes a gas flow comprising CH₂F₂, CF₄, O₂, and an inert gas and wherein a flow rate of CH₂F₂ is about 90 sccm, a flow rate of CF₄ is about 30 sccm, a flow rate of O₂ is about 15 sccm, and a flow rate of the inert gas is about 50 sccm, and wherein the plasma etch is conducted at a pressure of about 5 millitorr, at a power of about 550 watts and at a bias of about 300 volts;
conducting a soft etch on the surface of the gate electrode, including using an inorganic-based fluorine containing gas and an inert gas subsequent to conducting the plasma etch and a flow rate of SF₆ is about 5 sccm and the soft etch is conducted at a power of about 200 watts with a bias of about 0.0 volts and at a pressure of about 3 millitorr; and
siliciding the gate electrode with a metal subsequent to conducting the soft etch;
dielectric layers located over the silicided gate electrodes; and
interconnects formed over or within the dielectric layers that interconnect the silicided gate electrodes and the source/drains.
